(19) United States
(12) Patent Application Publication
(10) Pub. No.: US 2010/0176379 A1
(43) Pub. Date: Jul. 15, 2010

(54) SELF-ALIGNED ORGANIC THIN FILM TRANSISTOR AND FABRICATION METHOD THEREOF

(75) Inventors: Kang Dae Kim, Busan (KR); Taik Min Lee, Daejeon (KR); Hyeon Cheol Choi, Haenam-gum (KR); Dong Soo Kim, Daejeon (KR); Byun Oh Choi, Daejeon (KR)

Correspondence Address: HOLME ROBERTS & OWEN LLP, 1700 LINCOLN STREET, SUITE 4100, DENVER, CO, 80203, US

(73) Assignee: KOREA INSTITUTE OF MACHINERY & MATERIALS, DAEJEON (KR)

(21) Appl. No.: 12/278,120

(22) PCT Filed: May 30, 2008
(86) PCT No.: PCT/KR08/03019

§ 371 Date: Aug. 20, 2008

(30) Foreign Application Priority Data
Jul. 2, 2007 (KR) 10-2007-0066207

(51) Int. Cl. H01L 51/10; H01L 51/40

(52) U.S. Cl. 257/40; 438/99; 257/E51.006; 257/E51.001

(57) ABSTRACT

The present invention relates to a self-aligned organic thin film transistor (TFT) and a fabrication method thereof. According to the present invention, a gate electrode is formed from a first conductive layer patterned on a substrate, a gate dielectric layer is formed on top of the substrate to cover the gate electrode, and a second conductive layer is then formed on the gate dielectric layer. Subsequently, ultraviolet (UV) backside exposure for irradiating the second conductive layer with UV from a bottom side of the substrate using the gate electrode as a mask, and source/drain electrodes self-aligned with the gate electrode is then formed not to overlap with the gate electrode by developing the second conductive electrode. Thereafter, an organic semiconductor layer is formed between and on the source/drain electrodes. In the present invention, an organic TFT can be fabricated using a reel-to-reel process, and therefore, the fabrication process can be simplified.

### TECHNICAL FIELD

The present invention relates to an organic thin film transistor, and more particularly, to a self-aligned organic thin film transistor and a fabrication method thereof, wherein a conductive layer is directly patterned by performing backside exposure using a gate electrode as a mask to thereby form self-aligned source/drain electrodes.

### BACKGROUND ART

Recently, studies on the use of an organic compound as a semiconductor material have been actively conducted. In the field of thin film transistors (TFTs), studies on the use of an organic semiconductor such as pentacene instead of an inorganic material such as silicon have also been actively conducted. The organic semiconductor is synthesized by various methods, is easily formed in the shape of a fiber or film, and is relatively inexpensive in fabrication. Since it is possible to fabricate a device at a temperature of 100 C or less using the organic semiconductor, a plastic substrate can be used. In addition, the organic semiconductor has an excellent flexibility and conductivity, so that the organic semiconductor can be usefully applied to various types of flexible devices.

Hereinafter, a conventional organic TFT will be described with reference to the drawings. FIGS. 1 to 4 are sectional views illustrating a conventional organic TFT and a fabrication method thereof.

First of all, as shown in FIG. 1, a first conductive layer is deposited on a substrate 11 and patterned, thereby forming a gate electrode 12. Subsequently, as shown in FIG. 2, a gate dielectric layer 13 is formed on top of the substrate 11 to cover the gate electrode 12. Then, as shown in FIG. 3, a second conductive layer is deposited on the gate dielectric layer 13 and patterned, thereby forming source/drain electrodes 14. Thereafter, an organic semiconductor layer 15 is formed, as shown in FIG. 4.

In the conventional organic TFT 10, each of the source/drain electrodes 14 has a portion 16 partially overlapping with the gate electrode 12. The overlapping portion 16 formed between the two electrodes 12 and 14 induces parasitic resistance and parasitic capacity. Thus, there is a problem in that electrical characteristics of the organic TFT 10 may be lowered.

### DISCLOSURE OF INVENTION

### Technical Problem

Accordingly, an object of the present invention is to provide improve electrical characteristics of an organic TFT by preventing an overlapping portion from being formed between a source/drain electrode and a gate electrode.

Another object of the present invention is to simplify a fabrication method of an organic TFT.

### Technical Solution

In order to achieve these objects, the present invention provides a self-aligned organic TFT and a fabrication method thereof, wherein a conductive layer is directly patterned by performing backside exposure using a gate electrode as a mask, thereby forming self-aligned source/drain electrodes. Furthermore, the present invention provides a fabrication method of a self-aligned organic TFT using a reel-to-reel process.

A self-aligned organic TFT according to the present invention comprises a substrate; a gate electrode patterned and formed on the substrate; a gate dielectric layer covering the substrate and the gate electrode; source/drain electrodes formed on the gate dielectric layer so that they are self-aligned with the gate electrode and are not overlap with the gate electrode; and an organic semiconductor layer formed between and on the source/drain electrodes.

The gate dielectric layer may be formed of a UV transmittable dielectric material, and the source/drain electrodes may be formed of a UV curable conductive material.

A fabrication method of a self-aligned organic TFT according to the present invention comprises the steps of providing a substrate; forming a gate electrode from a first conductive layer patterned on the substrate; forming a gate dielectric layer on top of the substrate to cover the gate electrode; forming a second conductive layer on the gate dielectric layer; performing UV backside exposure for irradiating the second conductive layer with UV from a bottom side of the substrate using the gate electrode as a mask; forming source/drain electrodes self-aligned with the gate electrode not to overlap with the gate electrode by developing the second conductive layer; and forming an organic semiconductor layer between and on the source/drain electrodes.

The step of forming a gate electrode may include the step of covering the substrate with a shadow mask and thermally depositing the first conductive layer. Further, the step of forming a gate electrode may include the step of forming the first conductive layer on the substrate using any one of thermal deposition, e-beam evaporation, sputtering, micro contact printing and nano imprinting.

The step of forming a gate dielectric layer may be performed using a spin coating or laminating method. Preferably, the gate dielectric layer is formed of a UV transmittable dielectric material. Particularly, the gate dielectric layer may be formed of any one of poly-4-vinylphenol (PVP), polyimide, polyvinylalcohol (PVA), polystyrene (PS), and a mixed dielectric material of organic/inorganic materials.

The step of forming a second conductive layer may be performed using any one of screen printing, spray printing, inkjet printing, gravure printing, offset, reverse-offset, gravure-offset and flexography. Preferably, the second conductive layer is formed of a UV curable conductive material. Particularly, the second conductive layer may be in a paste or ink state in which a powdery conductive material is scattered in a UV curing resin.

The step of forming an organic semiconductor layer may be performed using a thermal deposition or inkjet printing method. Here, the organic semiconductor layer is preferably formed of any one of pentacene, tetracene, anthracene or TIPS pentacene[6,13-bis(triisopropylsilyethynyl)pentacene], P3HT[poly(3-hexylthiophene)], F8T2[poly(9,9-dioctylfluorene-co-bithiophene)], PQT-12[poly(3,3-didodecylquater-thiophene)] and PBTTT[poly(2,5-bis(3-tetradecylthiphene-2-yl)thieno[3,2-b]thiophene].

The substrate may be formed of plastic or glass.

In the meantime, the substrate may be provided in a reel shape. In such a case, at least two of the steps of forming a gate electrode, forming a gate dielectric layer, forming a second conductive layer, performing UV backside exposure, forming source/drain electrodes and forming an organic semiconductor may be consecutively performed while the reel-shaped substrate is continuously unwound and transferred.

### ADVANTAGEOUS EFFECTS

An organic TFT according to the present invention has a structure in which source/drain electrodes are formed to be self-aligned with a gate electrode and thus do not overlap with each other. Accordingly, electrical characteristics of the organic TFT can be improved.

Particularly, in the organic TFT of the present invention, a gate dielectric layer is formed of a UV transmittable dielectric material, and a second conductive layer for source/drain electrodes is formed of a UV curable conductive material. Therefore, UV backside exposure can be performed using the gate electrode as a mask, and the second conductive layer can be directly patterned instead of using a typical patterning method in which a photoresist pattern should be used. Accordingly, the source/drain electrodes self-aligned with the gate electrode can be formed, and the process can also be simplified. Furthermore, in the present invention, an organic TFT can be fabricated using a reel-to-reel process, and therefore, the entire fabrication processes can be simplified.

### BRIEF DESCRIPTION OF THE DRAWINGS

FIGS. 1 to 4 are sectional views illustrating a conventional organic TFT and a fabrication method thereof.

FIG. 5 is a sectional view showing the configuration of a self-aligned organic TFT according to an embodiment of the present invention.

FIG. 6 is a flowchart illustrating a fabrication method of a self-aligned organic TFT according to an embodiment of the present invention.

FIGS. 7 to 12 are sectional views illustrating respective processes in the fabrication method shown in FIG. 6.

FIG. 13 is a perspective view illustrating a reel-to-reel process in the fabrication method shown in FIG. 6.

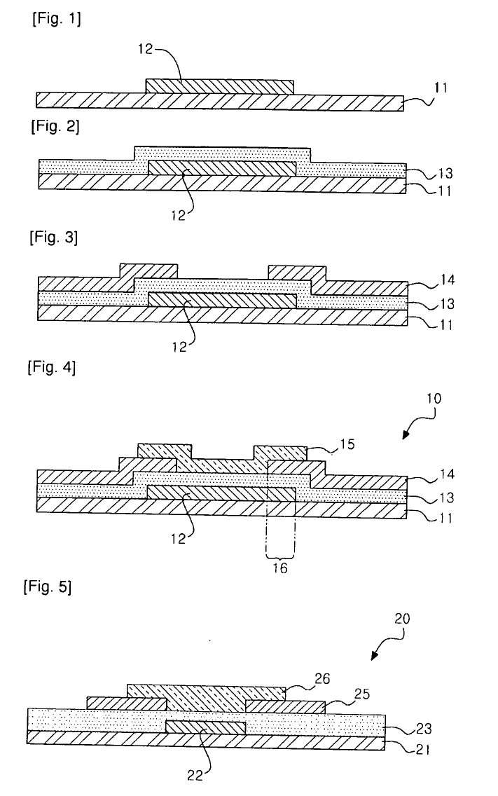

### BEST MODE FOR CARRYING OUT THE INVENTION

Hereinafter, embodiments of the present invention will be described in detail with reference to the accompanying drawings.

In the embodiments, technical descriptions which are well-known in the art to which the present invention pertains and are not directly related to the present invention will be omitted. This is to convey the subject manner of the present invention more clearly without obscuring it by omitting the unnecessary descriptions.

In the accompanying drawings, some components are shown schematically or to be exaggerated or omitted, and dimensions of each component do not entirely reflect the actual dimensions. Throughout the drawings, like reference numerals indicate like elements throughout the specification and drawings.

Configuration of Self-Aligned Organic Thin Film Transistor

FIG. 5 is a sectional view showing the configuration of a self-aligned organic TFT according to an embodiment of the present invention.

Referring to FIG. 5, the organic TFT 20 comprises a gate electrode 22 patterned and formed on a substrate 21; a gate dielectric layer 23 covering the substrate 21 and the gate electrode 22; source/drain electrodes 25 formed on the gate dielectric layer 23 to be self-aligned with the gate electrode 22; and an organic semiconductor layer 26 formed between and on the source/drain electrodes 25.

In the configuration of the organic TFT 20, the source/drain electrodes 25 are formed to be self-aligned with the gate electrode 22, so that no overlapping portion occurs. Accordingly, it is possible to prevent the problem that parasitic resistance and parasitic capacitance are generated in the overlapping portion 16 (see FIG. 4) as described in a conventional organic TFT, and electrical characteristics of the organic TFT 20 can be improved.

Hereinafter, a fabrication method of the organic TFT will be described. From the following description, the configuration of the aforementioned organic TFT will also become apparent.

Fabrication Method of Self-Aligned Organic Thin Film Transistor

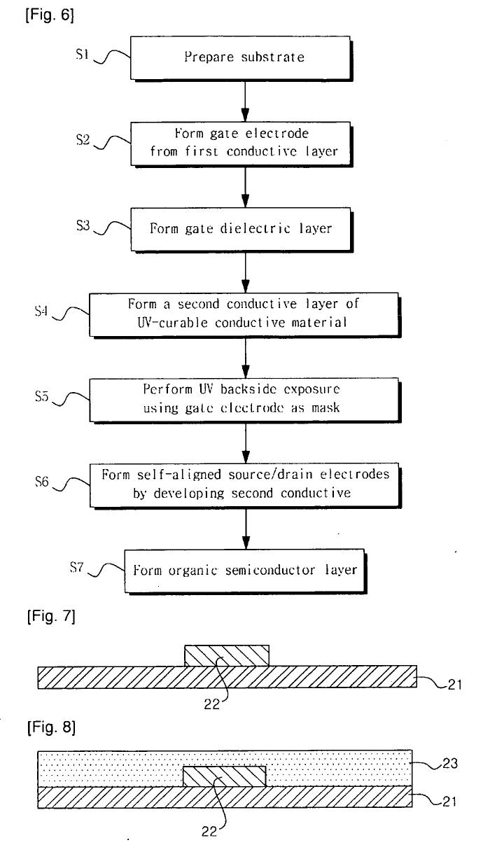

FIG. 6 is a flowchart illustrating a fabrication method of a self-aligned organic TFT according to an embodiment of the present invention, and FIGS. 7 to 12 are sectional views illustrating respective processes in the fabrication method shown in FIG. 6.

First of all, as shown in FIGS. 6 and 7, a substrate 21 is prepared (step S1). The substrate 21 is a glass or plastic substrate. A polymer compound such as polyimide, polyethylene naphthalate (PEN) or polyethylene terephthalate (PET) may be used as a material of the plastic substrate.

Thereafter, a gate electrode 22 is formed on the substrate 21 (step S2). The gate electrode 22 may be formed by a method of depositing and patterning a first conductive layer on the substrate 21 or by a method of covering the substrate 21 with a patterned mask and then depositing a first conductive layer. For example, in accordance with the latter method, the substrate 21 is covered with a shadow mask, and a thermal evaporation process is performed. In this case, the first conductive layer may be deposited up to a thickness of 400 at a deposition rate of 1/second, for example. Meanwhile, in the case of the former method, a process of patterning the first conductive layer may be performed using a well-known photolithography technique.

In step S2, the method of forming the first conductive layer may include e-beam evaporation, sputtering, micro contact printing, nano imprinting and the like, in addition to thermal evaporation. Generally, the gate electrode is formed of various kinds of metallic materials including Al, Cr, Mo, Cu, Ti, Ta and the like. However, the gate electrode may be formed of a non-metallic material with conductivity.

After the gate electrode 22 is formed, a gate dielectric layer 23 is formed on top of the substrate 21 to cover the gate electrode 22 as shown in FIGS. 6 and 8 (step S3). The gate dielectric layer 23 is formed using a method such as spin coating or laminating. For example, in case of spin coating, a dielectric material is applied with a 25 mm syringe for 30 seconds while rotating a chuck at 1000 rpm. Thus, the gate dielectric layer 23 may be formed to a thickness of about 5500. Thereafter, a baking process is performed in an oven of 100 C for 10 minutes or 200 C for 5 minutes.

An ultraviolet (UV) transmittable dielectric material is used as a material of the gate dielectric layer 23. For example, the gate dielectric layer 23 may include a material such as poly-4-vinylphenol (PVP), polyimide, polyvinylalcohol (PVA) and polystyrene (PS), and a mixed dielectric material of organic/inorganic materials such as aluminum oxide/polystyrene (Al₂O₃/PS).

For example, when the gate dielectric layer 23 is formed of PVP by a spin coating process, the PVP is mixed with a cross-linker in a solvent and then applied. At this time, propylene glycol monomethyl ether acetate (PGMEA) may be used as the solvent, and poly melamine-co-formaldehyde, which is known as CLA may be used as the cross-linker. The weight ratio of PGMEA to PVP to CLA is 100:10:5.

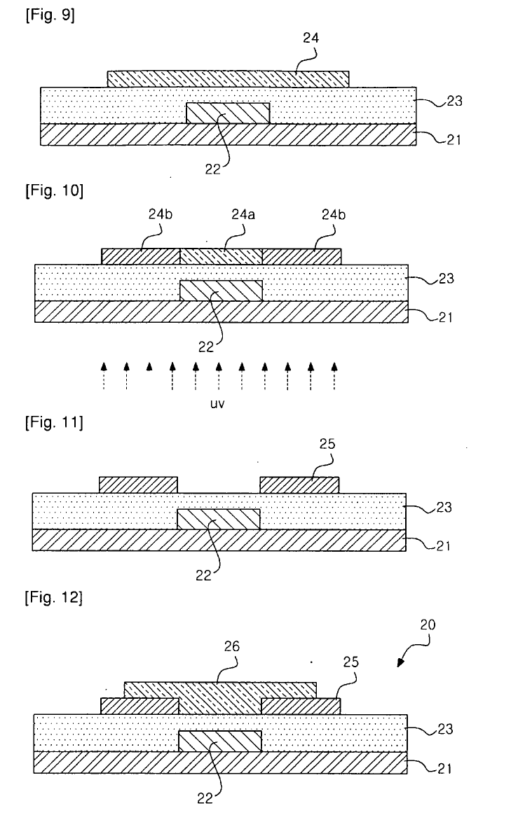

Then, as shown in FIGS. 6 and 9, a second conductive layer 24 is formed on the gate dielectric layer 23 (step S4). The second conductive layer 24, which is a layer to be patterned as source/drain electrodes in a subsequent process, is formed to overlap with the gate electrode 22 above the gate electrode 22. The forming method of the second conductive layer 24 may include any one of a screen printing, a spray printing, a gravure printing, an inkjet printing, an offset, a reverse-offset, a gravure-offset and a flexography. A UV-curable conductive material is used as a material of the second conductive layer 24. The material may be in a paste or ink state in which a powdery conductive material such as Ag, Au, Zn, Cu, carbon nano tube or conductive polymer is scattered in a UV curing resin. The UV curing resin contains a photoinitiator which reacts to UV energy.

Thereafter, as shown in FIGS. 6 and 10, UV backside exposure is performed (step S5). That is, the second conductive layer 24 is irradiated with UV from a bottom side of the substrate 20 using the gate electrode 22 as a mask. For example, the irradiation intensity of UV is 7 mW/cm², and the irradiation time of UV is 60 minutes. In the second conductive layer, the property of a portion 24a covered with the gate electrode 22 is maintained as it is, but a portion 24b that is not covered with the gate electrode 22 is cured by UV and then changed in its property. The second conductive layer is removed by a developer in a subsequent developing process, but the portion 24b, the property of which is changed by UV, is not removed by the developer.

More specifically, UV energy reacts with a photoinitiator contained in the UV curing resin to form a free radical, and a polymer is instantaneously formed by allowing the free radical to react with monomer or oligomer in the resin. The monomer or oligomer is liquid in a normal state (1 atmospheric pressure and 25 C). However, when strong UV energy is applied to the liquid, a polymerization reaction is induced, and then, the liquid is changed into a polymer that is solid in external appearance. That is, curing reaction is induced.

After the UV backside exposure is performed, source/drain electrodes 25 are formed by developing the second conductive layer 24 as shown in FIGS. 6 and 11 (step S6). For example, isopropyl alcohol (IPA) is used as a developer. As an example of the developing process, the second conductive layer is dipped in an IPA solution for 2 to 3 minutes and washed with the IPA solution. Thereafter, the second conductive layer is washed in flowing deionized (DI) water and then baked at a temperature of 120 C for 5 minutes.

As such, since the source/drain electrodes 25 are formed from the second conductive layer 24 exposed using the gate electrode 22 as a mask, they do not overlap with the gate electrode 22 through self-alignment. Accordingly, parasitic resistance and parasitic capacity can be eliminated, and electrical characteristics can be improved. Furthermore, instead of a typical patterning method in which a conductive layer is etched using a photoresist pattern, the second conductive layer 24 can be directly patterned, whereby the process can be very simplified.

Subsequently, as shown in FIGS. 6 and 12, an organic semiconductor layer 26 is formed between and on the source/drain electrodes 25 (step S7). Preferably, the organic semiconductor layer 26 is formed by a thermal deposition or inkjet printing method. At this time, the organic semiconductor layer 25 is preferably formed of any one of a low-molecular organic semiconductor, such as pentacene, tetracene, anthracene or TIPS pentacene[6,13-bis(triisopropylsilyethynyl) pentacene], and a polymer organic semiconductor, such as P3HT[poly(3-hexylthiophene)], F8T2[poly(9,9-dioctylfluorene-co-bithiophene)], PQT-12-[poly(3,3-didodecylquater-thiophene)] or PBTTT[poly(2,5-bis(3-tetradecylthiphene-2-yl)thieno[3,2-b]thiophene].

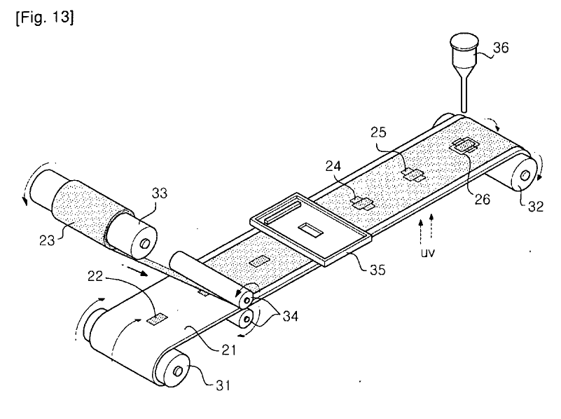

Meanwhile, a reel-to-reel process may be used in the aforementioned fabrication method of a self-aligned organic TFT. FIG. 13 is a perspective view illustrating a reel-to-reel process in the fabrication method shown in FIG. 6.

Referring to FIG. 13, a substrate 21 is provided in the shape of a reel, and all processes (at least two processes) are consecutively performed while the reel-shaped substrate 21 is continuously unwound and transferred. The substrate 21 is provided in a state of being wound around a first transfer roller 31, and is wound again around a second transfer roller 32 after a series of processes are performed. For example, a deposition process of a gate electrode 22 may be performed using micro contact printing or nano imprinting of the aforementioned processes, and a forming process of a gate dielectric layer 23 may be performed using laminating process. Reference numeral 33 designates a third transfer roller providing the gate dielectric layer 23 in a reel shape, and reference numeral 34 designates a pair of pressure rollers performing a laminating process.

A second conductive layer 24 to be used as source/drain electrodes 25 is formed through a screen printing process, wherein reference numeral 35 designates a screen printing mask and squeezer used herein. If the source/drain electrodes 25 are formed through the UV backside exposure and development processes, an organic semi-conductor layer 26 is formed through a dispensing process, for example. Reference numeral 36 designates a dispenser used herein.

### MODE FOR THE INVENTION

The reel-to-reel process of FIG. 13 is provided only for illustrative purposes, and the main processes are schematically illustrated. The present invention is not limited thereto. In addition, the aforementioned embodiments and terms used therein are used in a general meaning only for easily illustrating the subject matter of the present invention and helping understand the present invention and are not to limit the scope of the present invention. It will apparent to those skilled in the art that various modifications and changes in addition to the embodiments disclosed herein can be made thereto within the technical spirit of the present invention.

### INDUSTRIAL APPLICABILITY

An organic TFT according to the present invention has a structure in which source/drain electrodes are formed to be self-aligned with a gate electrode so that they do not overlap with each other. Accordingly, electrical characteristics of the organic TFT can be improved.

Particularly, in the organic TFT of the present invention, a gate dielectric layer is formed of a UV transmittable dielectric material, and a second conductive layer for source/drain electrodes is formed of a UV curable conductive material. Therefore, UV backside exposure can be performed using the gate electrode as a mask, and the second conductive layer can be directly patterned instead of a typical patterning method in which a photoresist pattern should be used. Accordingly, the source/drain electrodes self-aligned with the gate electrode can be formed, and the forming process can be simplified. Furthermore, in the present invention, an organic TFT can be fabricated using a reel-to-reel process, and therefore, it is possible to simplify the entire fabrication processes.

1. A self-aligned organic thin film transistor (TFT), comprising:
a substrate;
a gate electrode patterned and formed on the substrate;
a gate dielectric layer covering the substrate and the gate electrode;
source/drain electrodes formed on the gate dielectric layer so that they are self-aligned with the gate electrode and are not overlap with the gate electrode; and
an organic semiconductor layer formed between and on the source/drain electrodes.

2. The self-aligned organic TFT as claimed in claim 1, wherein the gate dielectric layer is formed of an ultraviolet (UV) transmittable dielectric material, and the source/drain electrodes is formed of a UV curable conductive material.

3. A method of fabricating a self-aligned organic TFT, comprising the steps of:
providing a substrate;
forming a gate electrode from a first conductive layer patterned on the substrate;
forming a gate dielectric layer on top of the substrate to cover the gate electrode;
forming a second conductive layer on the gate dielectric layer;
performing UV backside exposure for irradiating the second conductive layer with UV from a bottom side of the substrate using the gate electrode as a mask;
forming source/drain electrodes self-aligned with the gate electrode not to overlap with the gate electrode by developing the second conductive layer; and
forming an organic semiconductor layer between and on the source/drain electrodes.

4. The method as claimed in claim 3, wherein the step of forming a gate electrode includes the step of covering the substrate with a shadow mask and thermally depositing the first conductive layer.

5. The method as claimed in claim 3, wherein the step of forming a gate electrode includes the step of forming the first conductive layer on the substrate using any one of thermal deposition, e-beam evaporation, sputtering, micro contact printing and nano imprinting.

6. The method as claimed in claim 3, wherein the step of forming a gate dielectric layer is performed using a spin coating or laminating method.

7. The method as claimed in claim 3, wherein the gate dielectric layer is formed of a UV transmittable dielectric material.

8. The method as claimed in claim 3, wherein the gate dielectric layer is formed of any one of poly-4-vinylphenol (PVP), polyimide, polyvinylalcohol (PVA), polystyrene (PS), and a mixed dielectric material of organic/inorganic materials.

9. The method as claimed in claim 3, wherein the step of forming a second conductive layer is performed using any one of screen printing, spray printing, inkjet printing, gravure printing, offset, reverse-offset, gravure-offset and flexography.

10. The method as claimed in claim 3, wherein the second conductive layer is formed of a UV curable conductive material.

11. The method as claimed in claim 3, wherein in the step of forming a second conductive layer, the second conductive layer is in a paste or ink state in which a powdery conductive material is scattered in a UV curing resin.

12. The method as claimed in claim 3, wherein the step of forming an organic semi-conductor layer is performed using a thermal deposition or inkjet printing method.

13. The method as claimed in claim 3, wherein the organic semiconductor layer is formed of any one of pentacene, tetracene, anthracene or TIPS
pentacene[6,13-bis(triisopropylsilyethynyl) pentacene],
P3HT[poly(3-hexylthiophene)], F8T2-[poly(9,9-dioctylfluorene-co-bithiophene)],
PQT-12-[poly(3,3-didodecylquater-thiophene)] and
PBTTT[poly(2,5-bis(3-tetradecylthiphene-2-yl)thieno[3,2-b]thiophene].

14. The method as claimed in claim 3, wherein the substrate is formed of plastic or glass.

15. The method as claimed in claim 3, wherein the substrate is provided in a reel shape.

16. The method as claimed in claim 15, wherein at least two of the steps of forming a gate electrode, forming a gate dielectric layer, forming a second conductive layer, performing UV backside exposure, forming source/drain electrodes and forming an organic semiconductor are consecutively performed while the reel-shaped substrate is continuously unwound and transferred.
